(19) United States
(12) Patent Application Publication
(10) Pub. No.: US 2008/0092955 A1
(43) Pub. Date: Apr. 24, 2008

(54) Solar cell structures using porous column TiO2 films deposited by CVD

(75) Inventors: Fengyan Zhang, Vancouver, WA (US); Robert A. Barrowcliff, Vancouver, WA (US); Gregory M. Stecker, Vancouver, WA (US); Sheng Teng Hsu, Camas, WA (US)

Correspondence Address: David C. Ripma;Sharp Laboratories of America, Inc., 5750 NW Pacific Rim Boulevard, Camas, WA, 97202, US

(73) Assignee: Sharp Laboratories of America, Inc.

(21) Appl. No.: 11/582,197

(22) Filed: Oct. 16, 2006

(51) Int. Cl. H01L 31/00

(52) U.S. Cl. 136/263

(57) ABSTRACT

A method of fabricating a photovoltaic cell for use in a solar cell structure includes preparing a first substrate; preparing a TiO₂ precursor; preparing a cold wall CVD chamber; placing the first substrate in the cold wall CVD chamber; forming a transparent conducting electrode on the first substrate; depositing a porous column TiO₂ film on the transparent conducting electrode; depositing a photosensitive material in and on the porous column TiO₂ film; forming a top electrode on the photovoltaic cell; and incorporating the photovoltaic cell into a solar cell structure. The method of the invention is suitable for forming photovoltaic cells which may be of the dye-sensitized solar cell (DSSC) type, having a liquid or solid-state electrolyte therein, or an ordered organic-inorganic heterojunction photovoltaic cell.

### FIELD OF THE INVENTION

This invention relates to fabrication of solar cells, and specifically to a method using low temperature CVD methods to produce ordered, porous column structure anatase TiO₂ thin film for solar cell applications.

### BACKGROUND OF THE INVENTION

Anatase TiO₂ is a wide band gap semiconductor, having a band gap of about 3.2 eV. It may be used in dye-sensitized solar cell (DSSC) structures, in which case the mesoscopic TiO₂ is sensitized by a monolayer of sensitizer, such as cis-RuL₂(NCS)₂ that serves to harvest solar light. Upon excitation, an electron is injected into a conduction band of the TiO₂. The electrons migrate across the nanoparticles network to the current collector. Mesoscopic TiO₂ has a larger surface area than anatase TiO₂ film, which ensures efficient solar light harvesting by the currently employed sensitizer, however, mesoscopic TiO₂ does not provide a direct path to the excitable portion of the structure, which means that some electrons generated will be lost or recombined in the migrating pass. Gratzel, Dye-sensitized solid-state heterojunction solar cell, MRS Bulletin, Vol. 30, 23, (2005), describes replacement of a p-n junction solar cell by DSSCs.

Another type of solar cell structure is an organic-inorganic bulk heterojunction structure. This structure has an ordered array of inorganic semiconductor to increase its efficiency. In this case, all excitations are close enough to the organic-inorganic interface to be dissociated by the charge transfer, and all charge carriers have an uninterrupted pathway to the electrodes. Polymer chains may also be aligned to increase their charge mobility. A TiO₂ film having plural arrays of nanopores has been researched. The problem with known films is that the poles do not extend in a perpendicular, straight, parallel alignment from the top of the film to the bottom of the film, and tend to run parallel to the top and bottom of the film. Coakley et al., Ordered organic-inorganic bulk heterojunction photovoltaic cells, MRS Bulletin, Vol. 30, 37 (2005).

The ability to produce an ordered array of TiO₂ structures, having controllable size, density and porosity, will be useful in the fabrication of solar cell structures. Ordered arrays of TiO₂ structures have sufficient surface area and possess direct conduction paths, rather than the random nanoparticles network found in known materials. Integration of such arrays with organic semiconductor to make solid state DSSC, or ordered organic-inorganic bulk heterojunction structures, is fairly straight forward. The method of the invention uses CVD to grow porous column structures of TiO₂.

### SUMMARY OF THE INVENTION

A method of fabricating a photovoltaic cell for use in a solar cell structure includes preparing a first substrate; preparing a TiO₂ precursor; preparing a cold wall CVD chamber; placing the first substrate in the cold wall CVD chamber; forming a transparent conducting electrode on the first substrate; depositing a porous column TiO₂ film on the transparent conducting electrode; depositing a photosensitive material in and on the porous column TiO₂ film; forming a top electrode on the photovoltaic cell; and incorporating the photovoltaic cell into a solar cell structure. The method of the invention is suitable for forming photovoltaic cells which may be of the dye-sensitized solar cell (DSSC) type, having a liquid or solid-state electrolyte therein, or an ordered organic-inorganic heterojunction photovoltaic cell.

It is an object of the invention to provide a photovoltaic cell for use in a solar cell structure wherein the photovoltaic cell has a porous column TiO₂ film therein.

Another object of the invention is to provide a method which is suitable for forming photovoltaic cells which may be of the dye-sensitized solar cell (DSSC) type, having a liquid or solid-state electrolyte therein, or an ordered organic-inorganic heterojunction photovoltaic cell.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block diagram of the method of the invention.

FIG. 2 depicts a DSSC photovoltaic cell having a porous column TiO₂ film therein.

FIG. 3 depicts an ordered organic-inorganic heterojunction photovoltaic cell having a porous column TiO₂ film therein.

FIG. 4 is a SEM photo of a porous column TiO₂ film.

FIG. 5 is a SEM photo of a different morphology of a porous column TiO₂ film.

FIG. 6 is an XRD spectrum of a porous column TiO₂ film.

### DETAILED DESCRIPTION OF THE PREFERRED EMBODIMENTS

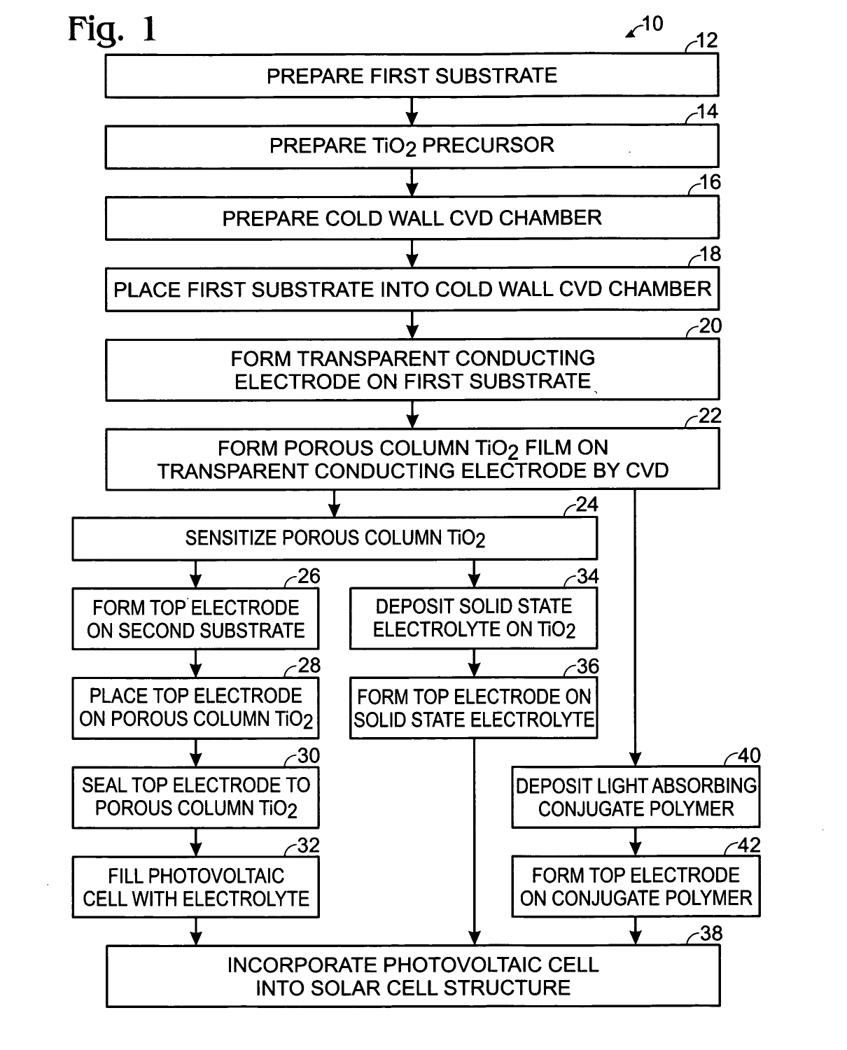

We have successfully grown high density porous column TiO₂ structures wherein the pore extend normal to the substrate, and extend directly from the top of the film to the bottom of the film. The method of the invention is depicted generally at 10 in FIG. 1. A first substrate is prepared, 12. In the preferred embodiment, the substrate is a glass or plastic substrate. A precursor is prepared, 14, which, in the preferred embodiment, is titanium isopropoxide (Ti (OC₃H₇)₄).

Preparation of a cold wall CVD chamber 16 includes maintaining both the precursor and the transport line at a temperature of between about 20° C. to 80° C. The substrate temperature is maintained between about 200° C. to 800° C.; and the pressure in the CVD chamber is maintained in the range of between about 1 torr. to standard atmosphere; The reaction gas is oxygen and the carrier gas is argon. Alternatively, other inert gases, such as nitrogen, may be used as the carrier gas. The cold wall CVD chamber has the first substrate placed therein, 18. The chamber is vacated to below 1 mtorr., and then oxygen or an oxygen and argon mixture is used to fill the chamber to the required growth pressure. The carrier gas flow and oxygen flow are in the range of between about 1 sccm to 1000 sccm.

The fabrication process for a photovoltaic cell follows the method of the invention, which provides fabrication techniques for a variety of photovoltaic cells, all of which use a porous column TiO₂ film as a support structure for various photosensitive materials. Once the deposition parameters are set in the CVD chamber, a transparent conducting electrode is formed 20 on the first substrate. The transparent conducting electrode may be formed of indium-tin-oxide (ITO) or SnO₂:F, deposited to a thickness of between about 10 nm to 1000 nm by CVD, PVD, spin-coating or electroplating. Next, a porous column TiO₂ film is deposited by CVD 22 to a thickness of between about 100 nm to 50 μm.

Once the porous column TiO₂ film is deposited, the stage is set for fabrication of a photovoltaic cell, which may be of the dye-sensitized solar cell (DSSC) type, having a liquid or solid-state electrolyte therein, or an ordered organic-inorganic heterojunction photovoltaic cell, as depicted by the three branches in FIG. 1. Common to the three embodiments of the method of the invention, a photosensitive material is deposited in and on the porous column TiO₂ film.

One form of the method of the invention includes sensitization 24 of the TiO₂ film using cis-RuL₂ (NCS)₂, or other suitable dye sensitizers.

When a liquid electrolyte is used with the DSSC, a top electrode is formed 26 on a second substrate. The top electrode is then placed in contact with the sensitized porous column TiO₂ film. The edge of the combined structure is sealed 30, and the space between the top and the bottom electrodes is filled 32 with a liquid electrolyte, such as lodolyte, an iodide-based redox electrolyte, to complete the cell.

When a solid-state electrolyte is used, such as spiro-MeOTAD, it may be deposited 34 on the sensitized porous column TiO₂ film by spin coating, CVD, screen printing, or any other state-of-the-art technique. A top electrode is formed 36 on the solid state electrolyte to complete the photovoltaic cell.

Alternatively, for an ordered organic-inorganic heterostructure photovoltaic cell, after step 22, a light absorbing conjugated polymer, such as P3HT, is deposited 40 and a top electrode is formed 42 to complete the photovoltaic cell.

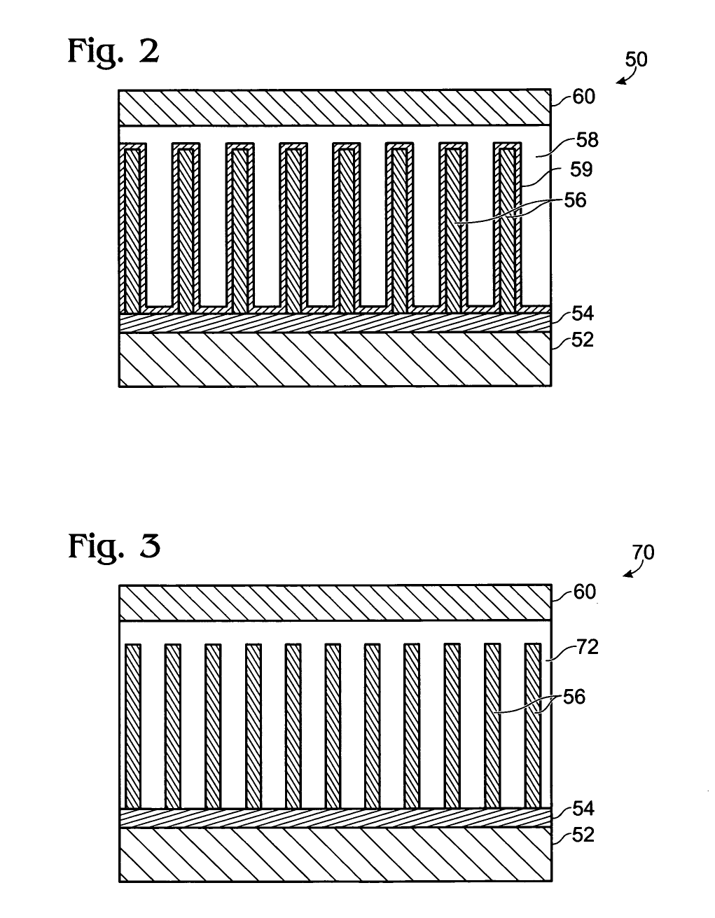

Referring now to FIG. 2, a DCCS photovoltaic cell is depicted generally at 50. The first substrate 52 is prepared according to the method of the invention, a transparent conductive electrode 54 formed thereon. The porous column TiO₂ film 56 is deposited by CVD. An electrolyte 58, either liquid or solid-state, is formed in the photovoltaic cell, as previously described. In this embodiment, a layer 59 of cis-RuL₂ (NCS)₂ is formed on porous column TiO₂ film 56. Top electrode 60 is formed.

FIG. 3 depicts an ordered organic-inorganic heterojunction photovoltaic cell at 70, which includes the same components as DCCS photovoltaic cell 50, except that the electrolyte is replaced by a light absorbing conjugated polymer 72.

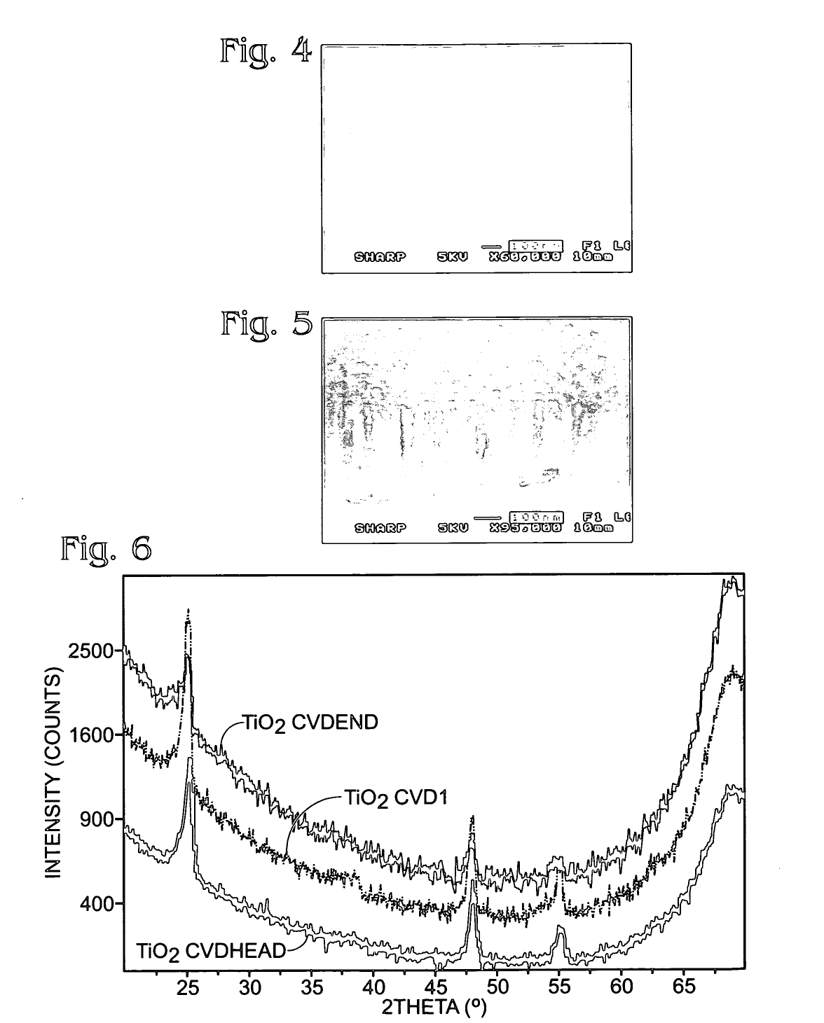

FIGS. 4 and 5 depict SEM photos of porous column TiO₂ structures, depicting different morphologies of the TiO₂ column structure. FIG. 6 is an XRD spectrum of the fabricated layer, which confirmed that the film is anatase TiO₂.

Thus, a method for fabricating a porous column TiO₂ film photovoltaic cell has been disclosed. It will be appreciated that further variations and modifications thereof may be made within the scope of the invention as defined in the appended claims.

We claim:

1. A method of fabricating a photovoltaic cell for use in a solar cell structure comprising:
preparing a first substrate;
preparing a TiO₂ precursor;
preparing a cold wall CVD chamber;
placing the first substrate in the cold wall CVD chamber;
forming a transparent conducting electrode on the first substrate;
depositing a porous column TiO₂ film on the transparent conducting electrode;
depositing a photosensitive material in and on the porous column TiO₂ film;
forming a top electrode on the photovoltaic cell; and
incorporating the photovoltaic cell into a solar cell structure.

2. The method of claim 1 wherein said depositing a photosensitive material in and on the porous column TiO₂ film includes depositing a dye sensitizer on the porous column TiO₂ film.

3. The method of claim 2 which includes forming a top electrode on a second substrate, sealing the top electrode to the porous column TiO₂ film, and filling the photovoltaic cell with a liquid electrolyte.

4. The method of claim 2 which includes depositing a solid-state electrolyte in and on the porous column TiO₂ and forming a top electrode on the solid-state electrolyte.

5. The method of claim 1 wherein said depositing a photosensitive material in and on the porous column TiO₂ film includes depositing a light absorbing conjugated polymer in and on the porous column TiO₂ and forming a top electrode thereon.

6. The method of claim 1 wherein said preparing a first substrate includes preparing a substrate taken from the group of substrates consisting of glass and plastic.

7. The method of claim 1 wherein said preparing a TiO₂ precursor includes preparing a titanium isopropoxide (Ti(OC₃H₇)₄) precursor.

8. A method of fabricating a photovoltaic cell for use in a solar cell structure comprising:
preparing a first substrate taken from the group of substrates consisting of glass and plastic;
preparing a titanium isopropoxide (Ti(OC₃H₇)₄) precursor to form a TiO₂ film;
preparing a cold wall CVD chamber;
placing the first substrate in the cold wall CVD chamber;
forming a transparent conducting electrode on the first substrate;
depositing a porous column TiO₂ film on the transparent conducting electrode;
depositing a photosensitive material in and on the porous column TiO₂ film;
forming a top electrode on the photovoltaic cell; and
incorporating the photovoltaic cell into a solar cell structure.

9. The method of claim 8 wherein said depositing a photosensitive material in and on the porous column TiO₂ film includes depositing a dye sensitizer on the porous column TiO₂ film, wherein the dye sensitizer is cis-RuL₂(NCS)₂.

10. The method of claim 9 which includes forming a top electrode on a second substrate, sealing the top electrode to the porous column TiO₂ film, and filling the photovoltaic cell with a liquid electrolyte, wherein the liquid electrolyte is lodolyte

11. The method of claim 9 which includes depositing a solid-state electrolyte in and on the porous column TiO₂ and forming a top electrode on the solid-state electrolyte, wherein the solid-state electrolyte is spiro-MeOTAD.

12. The method of claim 8 wherein said depositing a photosensitive material in and on the porous column TiO₂ film includes depositing a light absorbing conjugated polymer in and on the porous column TiO₂ and forming a top electrode thereon, wherein the light absorbing conjugated polymer is P3HT.
